(19) United States
(12) Patent Application Publication
(10) Pub. No.: US 2004/0078747 A1
(43) Pub. Date: Apr. 22, 2004

(54) Generalized forney algorithm circuit

(76) Inventors: David H. Miller, Sacramento, CA (US); Richard W. Koralek, Palo Alto, CA (US); Norman L. Swenson, Mountain View, CA (US)

Correspondence Address: Keith D. Nelson, Lockheed Martin Corporation, Building 220, Mail Stop A08, P.O. Box 49041, San Jose, CA, 95161-9041, US

(21) Appl. No.: 10/274,723

(22) Filed: Oct. 21, 2002

(51) Int. Cl. H03M 13/00

(52) U.S. Cl. 714/782; 714/784

(57) ABSTRACT

A decoder having no offset-adjustment factor for use in calculating error values in Reed-Solomon codes having code-generator-polynomial offset. The decoder comprises a generalized Forney algorithm circuit that processes encoded input data to generate decoded output data. The decoder comprises syndrome computation circuitry that computes syndromes derived from the input data, Berlekamp-Massey computational circuitry that converts the syndromes into error-location (lambda) and error-value (omega) polynomials and coefficients, and Chien-Forney circuitry that processes the lambda and omega coefficients to generate error locations and error values. The syndrome computation circuitry processes the encoded input data to generate syndromes. The syndromes are processed by the Berlekamp-Massey computational circuitry to generate the error-location (lambda) and error-value (omega) polynomials and coefficients. Chien-Forney circuitry processes the lambda and omega coefficients to generate error locations and error values. Exemplary Chien-Forney circuitry comprises Chien search circuitry including a Chien search algorithm that processes the lambda coefficients to generate error locations, formal derivative circuitry that computes a derivative of lambda comprising a sum of the odd terms of the lambda polynomials, omega search circuitry that evaluates the omega coefficients to produce an omega value, and Forney circuitry that processes the derivative of lambda and the omega value to generate error values.

### BACKGROUND

The present invention relates generally to circuits that implement Forney's algorithm, and more particularly, to a generalized Forney algorithm circuit having no offset-adjustment factor that may be used to calculate error values in Reed-Solomon codes having code-generator-polynomial offset.

The closest previously known solutions to the problem addressed by the present invention are disclosed in U.S. Pat. No. 5,396,502 entitled “Single-stack implementation of a Reed-Solomon encoder/decoder”, U.S. Pat. No. 5,170,399 entitled “Reed-Solomon Euclid algorithm decoder having a process configurable Euclid stack”, and U.S. Pat. No. 5,537,426 entitled “Operation apparatus for deriving erasure position .GAMMA.(x) and Forney syndrome T(x) polynomials of a Galois field employing a single multiplier”.

U.S. Pat. No. 5,396,502 discloses an error correction unit (ECU) that uses a single stack architecture for generation, reduction and evaluation of polynomials involved in the correction of a Reed-Solomon code. The circuit uses the same hardware to generate syndromes, reduce (x) and (x) polynomials and evaluate the (x) and (x) polynomials. The implementation of the general Galois field multiplier is faster than previous implementations. The circuit for implementing the Galois field inverse function is not used in prior art designs. A method of generating the (x) and (x) polynomials (including alignment of these polynomials prior to evaluation) is utilized. Corrections are performed in the same order as they are received using a premultiplication step prior to evaluation. A method of implementing flags for uncorrectable errors is used. The ECU is data driven in that nothing happens if no data is present. Also, interleaved data is handled internally to the chip.

U.S. Pat. No. 5,170,399 discloses a Reed-Solomon Galois field Euclid algorithm error correction decoder that solves Euclid's algorithm with a Euclid stack that can be configured to function as a Euclid divide or a Euclid multiply module. The decoder is able to resolve twice the erasure errors by selecting (x) and T(x) as initial conditions for (O)(x) and (O)(x), respectively.

U.S. Pat. No. 5,537,426 discloses operation apparatus for deriving an error position polynomial .GAMMA.(x) and a Forney syndrome polynomial T(x) of a Galois field capable of reducing the required number of Galois field multipliers to one, irrespective of the maximum error correction capacity in a Galois field operation, thereby reducing the chip area and achieving a correct operation. The operation apparatus comprises a storing register for storing result values sequentially inputted therein, a multiplexer for receiving outputs from the storing register and selecting a necessary coefficient therefrom, a first register and a second register for storing a coefficient currently selected by the multiplexer and a coefficient previously selected by the multiplexer, respectively, a multiplier for multiplying a value corresponding to an input erasure position and the coefficient stored in the second register, and an adder for adding a value outputted from the multiplier to the coefficient stored in the first register and inputting the resultant value to the storing register.

However, known prior art approaches requires circuitry to calculate an offset-adjustment factor. Also, known prior art approaches require a separate step (and additional time) to multiply or divide by any offset-adjustment factor. Prior art approaches require that the coefficients of the error-evaluator polynomial be loaded into different registers depending on the value of the offset. Furthermore, prior art approaches do not use a Forney circuit that is integrated with the Chien-search circuit in such a way that the result of the Chien-search differs by a non-zero factor from that obtained in the standard Chien-search approach while performing the same functionality as the standard Chien-search approach.

Forney's algorithm is used to find error values in Reed-Solomon error-correction systems. Implementation of Forney's algorithm requires the evaluation of the quotient of two polynomials. The standard textbook implementation of Forney's algorithm also requires the further step of multiplying this quotient by an adjustment factor for those Reed-Solomon codes which have a non-trivial offset value used to define the code generator polynomial. Calculation of the Forney adjustment factor in turn depends in detail on the value of the code offset. Calculation of, and multiplication by, the Forney adjustment factor adds significantly to the complexity of Forney's algorithm. Since the value of the adjustment factor varies depending on the code offset value, this complexity is even worse for system which use multiple codes with different offset values. Codes with non-trivial offset values are useful for various reasons, principally for simplifying the encoder circuits, but the resulting increased complexity and variability in the Forney circuit in the decides is a serious disadvantage.

Accordingly, it is an objective of the present invention to provide for a generalized Forney algorithm circuit having no offset-adjustment factor that may be used to calculate error values in Reed-Solomon codes having code-generator-polynomial offset.

### SUMMARY OF THE INVENTION

To accomplish the above and other objectives, the present invention provides for a generalized Forney algorithm circuit, or decoder, having no offset-adjustment factor that may be used to calculate error values in Reed-Solomon codes having code-generator-polynomial offset. The generalized Forney algorithm circuit eliminates calculation of offset-adjustment factors which allows a reduction in circuit size and increased speed. In systems that are required to handle Reed-Solomon codes with different offset values, the architecture of the present generalized Forney algorithm circuit is simplified by eliminating variations in the Forney algorithm for different offset values.

The present generalized Forney algorithm circuit or decoder is used in a Reed-Solomon BCH error correction decoder that processes encoded input data to generate decoded output data. The error correction decoder comprises syndrome computation circuitry for computing syndromes derived from the input data, Berlekamp-Massey computational circuitry that converts the syndromes into error-locator (lambda) and error-evaluator (omega) polynomials comprising error-location and error-value coefficients, and Chien-Forney circuitry that processes the error-location and error-value coefficients to compute and output error locations and error values.

An exemplary embodiment of the generalized Forney algorithm circuit or decoder comprises syndrome computation circuitry that divides the input data polynomials comprising the error-location and error-value coefficients and Chien-Forney circuitry that calculates error locations and error values from the polynomials and outputs them.

The Chien-Forney circuitry comprises Chien search circuitry comprising a Chien search algorithm that evaluates the error-locator (lambda) polynomials and outputs an error location flag. Formal derivative circuitry that computes a derivative of lambda comprising the sum of the odd terms of the error-locator (lambda) polynomials. Omega search circuitry that evaluates the omega coefficients to produce an omega value. Forney circuitry comprising Forney's algorithm that processes the derivative of lambda and the error-evaluator (omega) polynomials to compute the error value.

The generalized Forney algorithm circuit of the present invention eliminates extra steps involving the adjustment factor in Forney's algorithm for codes with any and all code offset values and therefore allows an implementation which is both simple and also independent of the code offset value. The present invention avoids both multiplying by any adjustment factor and event the need to calculate any adjustment factor in the first place. The resulting simplification of the Forney circuit makes it easier to implement Reed-Solomon codes with non-trivial offset values and is especially useful in any system which must decode several different Reed-Solomon error-correction codes which have multiple different offset values.

In addition, the decoder uses a unique circuit for Galois-field division, a novel circuit to perform Forney's algorithm which makes possible programmability among different code polynomials. For example, the Chien-Forney module used in the decoder provides for a further degree of programmability, involving the “code-generator polynomial” that may also easily be introduced into the decoder at the gate array level or with on-chip programmability. A dual-mode BCH configuration is implemented that can handle two parallel BCH code words at once. A massively parallel Galois-field multiplier structure is used in the Berlekamp-Massey module, and readout and test capabilities are provided.

The Chien-Forney implementation allows changes in code offset and skip values to be implemented solely through gate-array changes in exclusive-OR trees in syndrome and Chien-Forney modules.

A reduced-to-practice embodiment of the decoder has been fabricated as a CMOS gate array but may be easily implemented using gallium arsenide or other semiconductor technologies.

### BRIEF DESCRIPTION OF THE DRAWINGS

The various features and advantages of the present invention may be more readily understood with reference to the following detailed description taken in conjunction with the accompanying drawings, wherein like reference numerals designate like structural elements, and in which:

FIG. 1 is a block diagram illustrating the architecture of an exemplary programmable, systolic, Reed-Solomon BCH error correction decoder in which the present invention may be advantageously employed;

FIG. 2 illustrates the topology of the exemplary decoder shown in FIG. 1;

FIG. 3 is a block diagram illustrating an exemplary architecture of a syndrome-Chien-Forney circuit, or generalized Forney algorithm circuit, in accordance with the principles of the present invention;

FIG. 4 illustrates an exemplary syndrome computation circuit employed in the exemplary generalized Forney algorithm circuit;

FIG. 5 illustrates an exemplary Chien search circuit employed in the exemplary generalized Forney algorithm circuit;

FIG. 6 illustrates an exemplary circuit employed in the exemplary generalized Forney algorithm circuit that outputs the formal derivative of lambda and error location flag; and

FIG. 7 illustrates an exemplary omega search circuit employed in the exemplary generalized Forney algorithm circuit.

### DETAILED DESCRIPTION

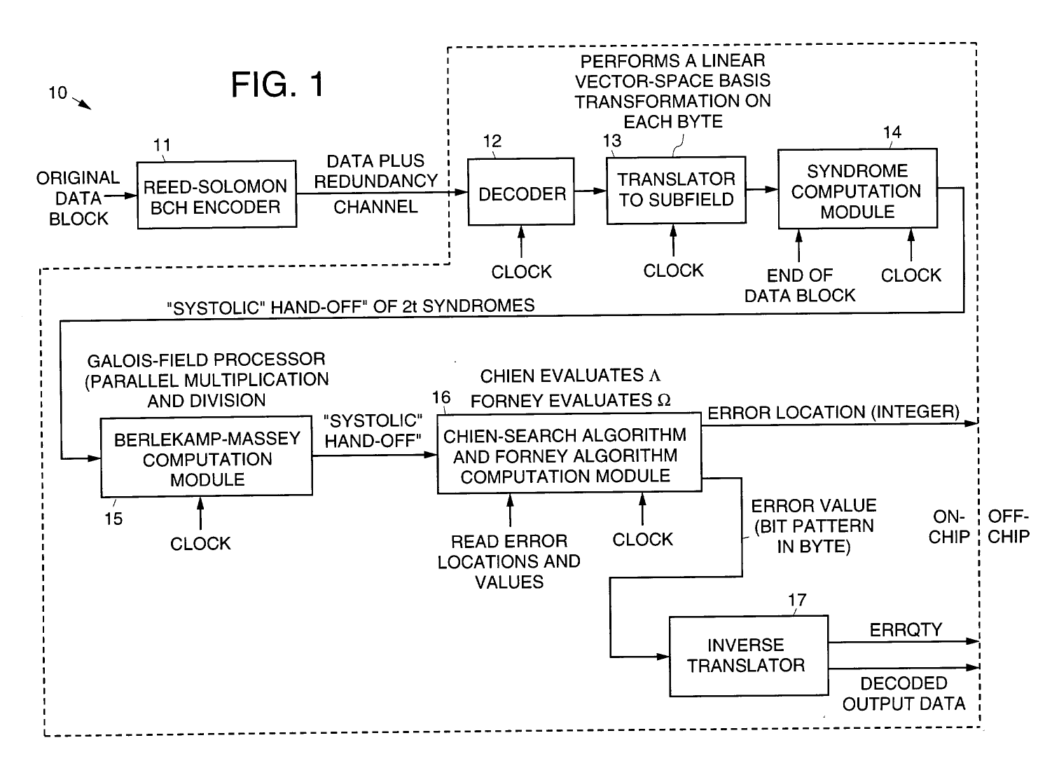

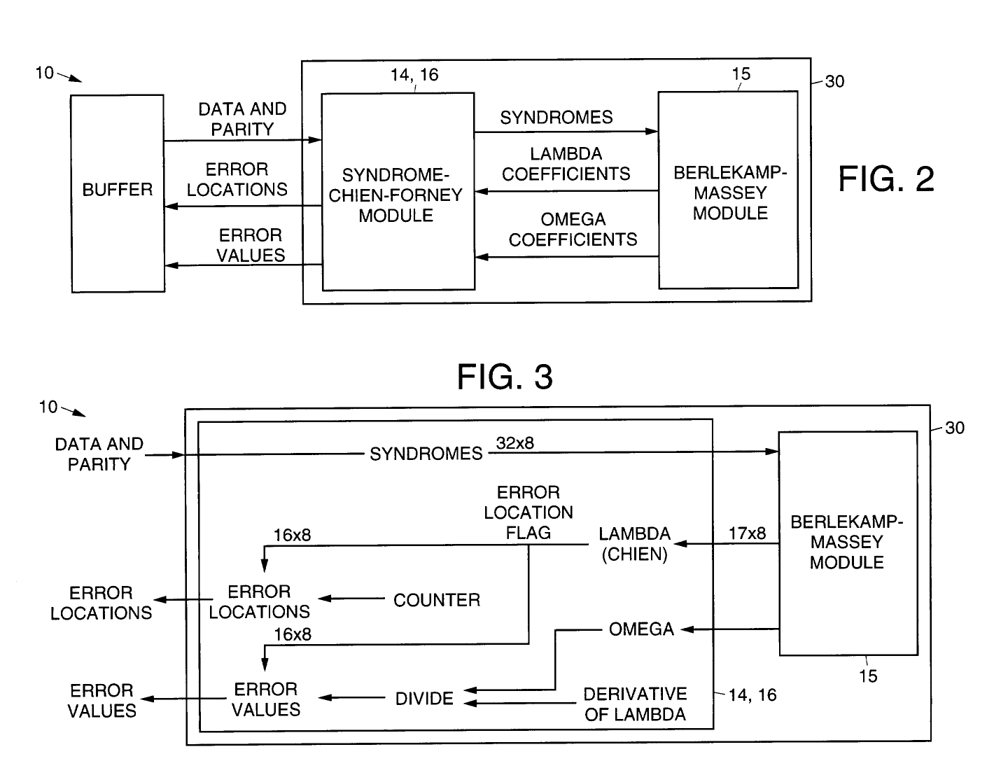

Referring to the drawing figures, FIG. 1 is a block diagram illustrating an exemplary architecture of a programmable, systolic, Reed-Solomon BCH error correction decoder 10. A generalized Forney algorithm circuit 20 or decoder 20 (FIGS. 2 and 3) in accordance with the principles of the present invention may be advantageously employed in the exemplary decoder 10 shown in FIG. 1.

As is shown in FIG. 1, the decoder 10 includes a subfield translator 13 that processes encoded input data to perform a linear vector-space basis transformation on each byte of the data. The subfield translator 13 is coupled to a syndrome computation module 14 or circuit 14 which performs parity checks on the transformed data and outputs 2t syndromes. The syndrome computation module 14 is coupled to a Berlekamp-Massey computation module 15 that implements a Galois-field processor comprising a parallel multiplier and divider that converts the syndromes into lambda (Λ) and omega (Ω) polynomials. The Berlekamp-Massey computation module 15 is coupled to a Chien-Forney module 16 (comprising the generalized Forney algorithm circuit 16 or decoder 16) that calculates error locations and error values from the polynomials and outputs them. An inverse translator 17 performs an inverse linear vector-space basis transformation on each byte of the calculated error values.

An original data block is encoded by a Reed-Solomon BCH encoder 11 which outputs data over a channel to a Reed-Solomon decoder 12 that decodes the Reed-Solomon encoding. The subfield translator 13 performs a linear vector-space basis transformation on each byte of the data. The syndrome computation module 14 performs parity checks on the transformed data and outputs syndromes. The Berlekamp-Massey computation module 15 (Galois-field processor) converts the syndromes into lambda (Λ) and omega (Ω) polynomials. The Chien-Forney module 16 calculates error locations and error values from the polynomials and outputs them. The Chien algorithm evaluates the lambda (Λ) polynomials and the Forney algorithm evaluates the omega (Ω) polynomials. The inverse translator 17 performs an inverse transform on each byte of the data to translate between the internal chip Galois-field representation and the external representation that is output from the decoder 10.

Thus, the error correction decoder 10 comprises three basic modules, including the syndrome computation module 14, the Berlekamp-Massey computation module 15, and the Chien-Forney module 16. The syndrome computation module 14 calculates quantities known as “syndromes” which are intermediate values required to find error locations and values. The Berlekamp-Massey computation module 15 implements a Berlekamp-Massey algorithm that converts the syndromes to other intermediate results known as lambda (Λ) and omega (Ω) polynomials. The Chien-Forney module 16 uses modified Chien-search and Forney algorithms to calculate the actual error locations and error values.

To carry out the mathematical calculations involved in decoding Reed-Solomon and BCH error-correction codes, mathematical structures known as “Galois fields” are employed. For a given-size symbol, there are a very large number of mathematically-isomorphic but calculationally distinct Galois fields. Specification of a Reed-Solomon code requires choosing not only values for n and k (in the (n, k) notation) but also choosing a Galois-field representation. Two Reed-Solomon codes with the same n and k values but different Galois-field representations are incompatible in the following sense: the same block of data will have different redundancy symbols in the different representations, and a circuit that decodes a Reed-Solomon code in one representation generally cannot decode a code using another Galois-field representation. This is not true for BCH codes.

From the viewpoint of a Reed-Solomon decoder, the Galois-field representation is commonly given by external constraints set in an encoder in a transmitter for data transmission applications or an encoder in a write circuit for data storage applications. This normally precludes choosing a representation that will optimize the operations required internally in the decoder 10 to find the errors.

In the decoder 10, the externally given Galois-field representation is not optimal for internal integrated circuit operations. Therefore, a different Galois-field representation is used on-chip than is used external to the chip. An internal representation was chosen by computer analysis to maximize global chip speed and, subject to speed maximization, to minimize global chip gate count. The translator circuit 13 is used at the front end of the decoder 10 and the inverse translator circuit 17 is used at the back end to translate between the internal chip Galois-field representation and the external representation.

The internal Galois-field representation is a “quadratic subfield” representation. The fact that a quadratic-subfield representation is used is not in and of itself particularly significant. Rather, it is the use of a separate Galois-field representation on-chip, distinct from the representation used for incoming data, which representation is chosen to globally optimize chip speed and performance, and the use of the translator and inverse translator circuits 13, 17.

The Berlekamp-Massey module 15 carries out repeated dot product calculations between vectors with up to seventeen components using Galois-field arithmetic. The usual textbook method of doing this is to have a single multiplication circuit as part of the Galois-field arithmetic logic unit (ALU). Instead, in the decoder 10, seventeen parallel multipliers are used to carry out the dot product in one step. This massive parallelism significantly increases speed, and is made feasible because of the optimizing choice of an internal Galois-field representation that is different from the representation used off-chip.

Both the Berlekamp-Massey Galois-field ALU and the Forney algorithm section of the Chien-Forney module 16 require a circuit that rapidly carries out Galois-field division. The integrated inverter-multiplier circuit implements a power-subfield Galois-field divider circuit to perform this function which combines subfield and power methods of multiplicative inversion. The integrated inverter-multiplier circuit or power-subfield Galois-field divider circuit may be used in a wide variety of applications not limited to use with the decoder 10, or to Reed-Solomon and BCH codes, such as in algebraic-geometric coding systems, and the like.

In the course of carrying out the Berlekamp-Massey algorithm, the Berlekamp-Massey module 15 repeatedly computes dot products of two vectors stored in two shift registers. Often the multiplier or multiplicand is zero. To carry out the multiplication in such a case wastes substantial time since multiplication is much slower than shifting the shift register. By avoiding zero multiplies, substantial time is saved.

There are several ways to do this. First, for a given code, parts of the shift register are always zero. Second, for a given code, at any particular point in the calculation, mathematically, some stages in the shift register will be zero. Finally, some coefficients may be fortuitously zero. A zero detect can be performed to avoid multiplication whenever it would be a zero multiply (in general, the lambda register is more likely zero compared to the syndrome register) or counters can set up to avoid zero multiplies when the counter indicates that a shift register entry must be zero.

Repeated multiplies are carried out in the Berlekamp-Massey module 15, and in particular, the Galois-field ALU. There are several methods by which the Galois field multiplications may be done. A random-logic multiply operation may be performed, which is relatively straightforward but is a relatively large circuit that is slow, using asynchronous feed-forward logic.

There are two slightly different approaches that trade off size versus speed. Standard log/antilog tables may be employed, especially in a CMOS decoder 10. This approach requires a separate log and antilog table (each 256 by one byte for 255 codes). This approach also requires a mod 255 binary adder. Depending on the speed of the table look-ups and the speed of the binary adder, this approach may be significantly faster than the random-logic multiply approach.

Subfield log and antilog tables may be used, which requires much smaller tables (by about a factor of eight for the 255 codes). However, this approach uses translation circuits at the input and output of the multiplier to go back and forth from the standard to the subfield representation. It is also necessary to perform a subfield divide (and to have control circuitry for the divide-by-zero case) and to do two extra binary additions. This approach is slower than the log/antilog approach but requires less circuitry.

It is also possible to perform a direct multiply in the subfield. If translation in and out of the subfield is not required, this approach has about a twenty percent lower gate count than a random-logic multiply and a slightly higher speed. Translation into and out of the subfield for each multiply results in negligible savings. However, the translation circuits are shared, using a subfield divider.

Dividing may be accomplished using a staged divider. In the case of 255 codes, four random-logic multipliers (or subfield multipliers) are combined and small parity trees are used to generate the multiplicative inverse. To carry out a divide using this approach, the inverse is found and then a multiply is performed.

However, in the Berlekamp-Massey module 15, divides are carried out very rarely, so that the speed is not that relevant. Also, four multipliers may be used in parallel for standard multiply operations, so that the gate count is not affected.

Standard log/antilog tables may be used as in the multiplicative case. A binary subtractor mod 255 may be used to directly perform division or the log of the multiplicative inverse (which means just 1's complementing the logarithm) and then add logs to multiply.

Subfield log/antilog tables may be used as in the multiplicative case. Subfield division has substantial advantages over a staged divider in terms of speed and size, even including the translation circuits between subfield and standard representations.

Standard textbook algorithms require a separate calculation of a quantity known as the “formal derivative of the lambda polynomial”. This separate calculation is avoided by absorbing it into the Chien search algorithm. The syndrome calculation circuits, including the parity trees, are re-used for the Chien search. There are two alternative ways to do the Chien search. The same syndrome registers may be used for the code or the lowest order syndrome registers can be used.

FIG. 2 illustrates the overall topology of the exemplary decoder 10 shown in FIG. 1. The decoder 10 (integrated circuit) is shown as including two basic modules, comprising a syndrome-Chien-Forney module 20 comprising the present generalized Forney algorithm circuit 20 or decoder 20, which includes the syndrome computation module 14 and the Chien-search algorithm and Forney algorithm computation module 16 shown in FIG. 1 along with the Berlekamp-Massey module 15. FIG. 3 is a top-level block diagram illustrating the architecture of the syndrome-Chien-Forney circuit 20, or generalized Forney algorithm circuit 20, in accordance with the principles of the present invention. In FIG. 3 and the remaining drawing figures, all data paths are 8 bits wide.

The generalized Forney algorithm circuit 20 is preferably embodied in an integrated circuit. A reduced-to-practice embodiment of the Forney algorithm circuit 20 was implemented in a CMOS gate array. However, it is completely straightforward to implement the decoder using any standard semiconductor technology, including, but not limited to, gallium arsenide gate arrays or gallium arsenide custom chips.

Referring to FIGS. 2 and 3, the sequence of steps to decode a Reed-Solomon or BCH codeword is as follows. A complete codeword is assembled in the buffer (FIG. 2). The decoder 10 generally requires several parallel decoder chips, and this paralleling is handled by the buffer.

The codeword (data and parity) is fed to the syndrome circuit 14 in the syndrome-Chien-Forney module, which computes quantities known as syndromes. For both Reed-Solomon and BCH codes, there are 2t syndromes of 8 bits each.

The syndromes are transferred to the Berlekamp-Massey module 15. The Berlekamp-Massey module 15 performs a complicated iterative algorithm, using the syndromes as input, to compute an error-locator polynomial (Lambda) and an error-evaluator polynomial (Omega). The output of the algorithm includes (t+1) Lambda coefficients and (t+1) Omega coefficients, where each coefficient is 8 bits for the Reed-Solomon codes and the BCH(255) codes.

The Lambda coefficients and the Omega coefficients are then transferred back to the syndrome-Chien-Forney module 20. In this module, the Lambda coefficients (the coefficients of the error-locator polynomial) are used in a Chien search circuit 14b (FIG. 5) that performs a Chien search, resulting in the error locations. The Chien search circuit 14b is a feedback-shift-register-based circuit that is shifted for n cycles and whose output indicates that the symbol corresponding to that shift contains an error. The Omega coefficients (the coefficients of the error-evaluator polynomial), along with the formal derivative of Lambda, are used in Forney's algorithm to compute the error values (for Reed-Solomon codes only). The Forney algorithm circuit includes two feedback shift registers (one is actually just some added logic attached to the Lambda shift register) plus a Galois-field divider.

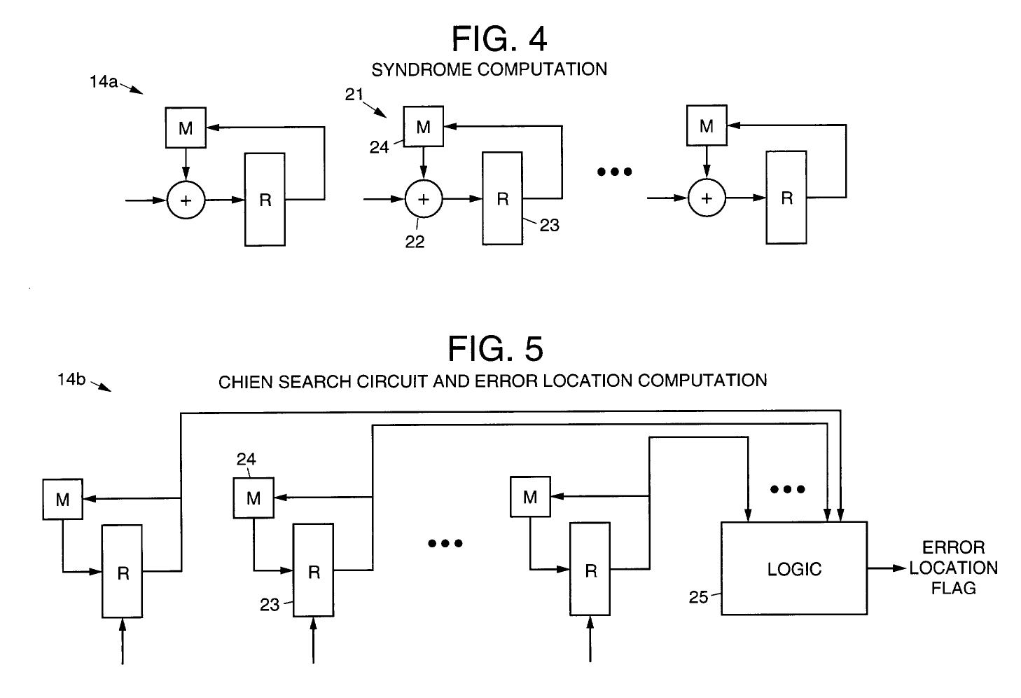

FIG. 4 illustrates an exemplary syndrome computation circuit 14a that may be employed in the exemplary generalized Forney algorithm circuit 20.

The syndrome computation is performed by dividing the incoming codeword by each of the factors of the generator polynomial. This is accomplished with a set of one-stage feedback shift registers 21, as shown in FIG. 4. The one-stage feedback shift registers 21 each comprise an adder 22 whose output is coupled through a shift register 23 to a matrix 24, whose output is summed by the adder 22 with an input. The matrices (M) 24 shown in FIG. 4 are switchable between Reed-Solomon codes and BCH codes.

The following gives a rough estimate of the basic circuitry in the syndrome computation register: (a) registers [symbol] 32 registers×8 flip-flops=256 flip-flops, (b) matrices [symbol] 32 matrices×average 40 XORs=1280 XORs, (c) adders [symbol] 32 adders×8 XORs=256 XORs.

FIG. 5 illustrates an exemplary Chien search circuit 14b that may be employed in the generalized Forney algorithm circuit 20. The error locations are found by finding the roots of the error locator polynomial (lambda). This is done by using the Chien search, implemented with the Chien search circuit 14b described below. The Chien search circuit 14b shown in FIG. 5 includes (t+1) stages, each 8 bits wide. The stages are loaded with the coefficients of the error locator polynomial lambda (from the Berlekamp-Massey algorithm), and the Chien search circuit 14b is clocked in synchronism with a byte counter. The error flag output of the Chien search circuit 14b is a “1” when the byte number corresponding to the byte counter is one of the bytes that is in error. Registers are provided to store the error byte numbers as they are found.

The following gives a rough estimate of the basic circuitry in the Chien search register: (a) Registers [symbol] 17 registers×8 flip-flops=136 flip-flops, (b) Matrices [symbol] 17 matrices×average 40 XORs=680 XORs, (c) Logic block [symbol] 17×8 input XOR tree=136 XORs.

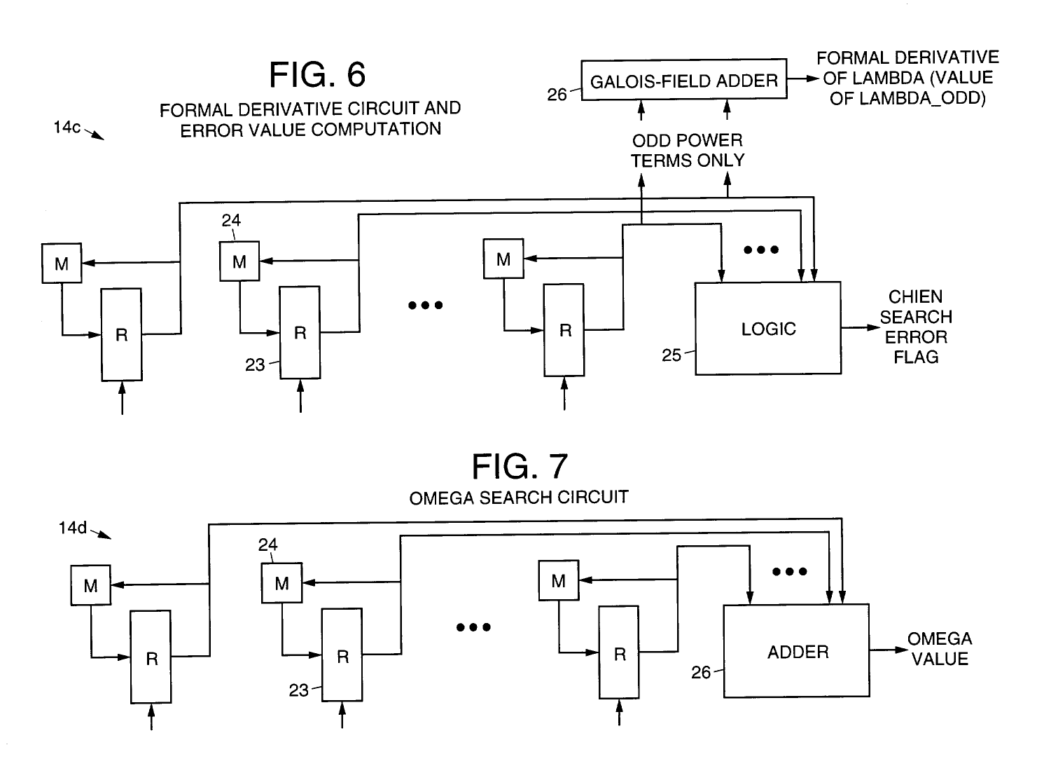

FIG. 6 illustrates an exemplary circuit 14c employed in the generalized Forney algorithm circuit 20 that outputs the formal derivative of lambda and error location flag. The error value (i.e., which bits in the erroneous byte are in error) is computed using Forney's algorithm. When the Chien search indicates that a root of lambda has been found, the error value is determined by dividing the error evaluator polynomial omega by the value of the odd part of lambda, both evaluated at the root.

The standard textbook implementation of Forney's algorithm requires a separate calculation of a quantity known as the formal derivative of lambda: this would require a separate set of shift registers similar to those shown in FIG. 6 for the Chien search circuit 14b, except that it would only require half as many stages (because, when taking a derivative over a field of characteristic 2, the even powers disappear).

However, in the present invention, a novel method is employed to carry out Forney's algorithm, wherein, rather than requiring the formal derivative of lambda, only the sum of the odd terms of lambda are required. This may simply be accomplished by attaching a set of Galois-field adders 26 (or lambda-odd circuit 26) to the Chien search registers 23, as shown in FIG. 6. This significantly reduces circuit size and complexity.

An omega evaluation or search circuit 14d, shown in FIG. 7, is also similar to the Chien search circuit 14b. The t registers 23 are loaded with the omega coefficients and the circuit 14d is clocked in a manner identical to the Chien search circuit 14b of FIG. 5.

The output of the omega search circuit 14d is divided by the output of the lambda-odd circuit 26 to produce the error value, i.e., the actual bit-wise pattern of errors in a particular byte. The Galois field divider circuit will be discussed in conjunction with the Berlekamp-Massey algorithm. This error value is fed through the inverse translator circuit 17 shown in FIG. 1 to convert it to an off-chip Galois-field representation and is then bit-by-bit XORed with the received byte to correct it. Registers 23 are provided to store the error byte values as they are found.

In the standard implementations of Forney's algorithm for Reed-Solomon codes with code-generator polynomial offsets (which include the codes used in the present invention), it is necessary to employ an additional circuit in the Forney module to multiply by an offset-adjustment factor. In the present invention, the novel modification of Forney's algorithm which is employed does not require calculation of, or multiplication by, any offset-adjustment factor, thereby increasing speed and reducing circuit size and complexity.

The following gives a rough estimate of the basic circuitry in the omega search register: (a) Registers [symbol] 17 registers×8 flip-flops=136 flip-flops, (b) Matrices [symbol] 17 matrices×average 40 XORs=680 XORs, (c) Logic block [symbol] 17×8 input XOR tree=136 XORs. In addition, a Galois Field divider circuit 40, an 8-bit binary counter, and the registers are added to store the error locations and error values: (a) divider [symbol] 173 XORs plus 144 ANDs, (b) counter [symbol] 1 NOT plus 7 XORs plus 6 ANDs, (c) registers [symbol] 32×8 flip-flops=256 flip-flops.

The generalized Forney algorithm circuit 20 comprises a circuit for carrying out the Forney algorithm for use with Read-Solomon codes with “offsets”. This circuit 20 requires fewer stages for the calculation and can perform at higher speed than conventional Forney-algorithm circuits. This Chien-Forney circuit 20 may be used in a wide variety of applications not limited to the exemplary decoder 10.

In an alternative implementation involving changes or programmability in XOR-trees in the syndrome module 14 and XOR trees in the Chien-Forney module 16, the decoder 10 may handle codes with different code-generator polynomials. Reed-Solomon codes are defined by a choice of the size of the code symbol (one byte in the disclosed embodiment of the decoder 10), by the choice of the field-representation (which may be varied in the decoder 10 by altering the translator/inverse-translator circuits 13, 17), and by the choice of a specific code-generator polynomial. The code-generator polynomial is specified using an “offset” and a “skipping value” for the roots of the polynomial.

By using the Chien-Forney implementation embodied in the Chien-Forney module 16, a change in offset or skipping value for the code-generator polynomial can be handled by solely changing the XOR trees in the syndrome and Chien-Forney modules 14, 16 without any changes whatsoever in the Berlekamp-Massey module 15. Such changes in the XOR trees may be made by making changes in the gate array or by introducing further programmability into the syndrome and Chien-Forney modules 14, 16.

Typically, the construction of the Chien search algorithm causes error locations and values to naturally come out in the reverse order to the order in which the data flows through the decoder 10, which complicates correction of the errors. In the decoder 10, on the contrary, error locations and values come out in forward order to facilitate on-the-fly error correction.

In any error-correction system, a certain fraction of error patterns that cannot in fact be corrected nonetheless “masquerade” as correctable error patterns. These masquerading error patterns are wrongly corrected, adding additional errors to the data. The decoder 10 has been designed so as to detect all uncorrectable patterns in the Reed-Solomon codes which are mathematically detectable. Thus, the fraction of uncorrectable patterns in the Reed-Solomon codes that “masquerade” as correctable patterns when using the decoder 10 is the absolute minimum that is mathematically allowed. The decoder 10 meets this theoretically optimal performance criterion.

In the syndrome module 14, syndrome registers 23 used for the Reed-Solomon codes are re-used for the BCH codes. This requires switching between the exclusive-or trees which are used in the syndrome module 14.

Certain “trees” of exclusive-or (XOR) logic gates are required in both the syndrome and Chien-Forney modules 14, 16. In an alternative implementation of the decoder 10, these XOR trees and the accompanying registers that are used in the syndrome module are also used in the Chien-search module 16. This alternative implementation may be used to minimize the area of the decoder integrated circuit, but this results in a significant reduction in the rate of data throughput

For ease and flexibility in outputting final results, the output of the Chien-Forney module 16 may be double-buffered. Double-buffering allows the error results from one code word to be read out while the chip is processing the next code word. Furthermore, this allows a fairly long time for the error results to be read out, thereby relaxing the requirements on external circuitry that reads the results. One output of the decoder 10 is ERRQTY (FIG. 1), which is a signal indicative of the number of errors detected by the decoder 10 in a code block. The other output is the error location, which is an integer value indicative of the location (bit position) of the error.

Additional details regarding the present invention are presented below.

The mathematics of Reed-Solomon codes implies that given a symmetric generator polynomial, the syndromes cannot start with S1. Indeed, the matter is quite rigid, if an even number of syndromes is desired, the syndrome indices must be centered on 127½ for a code over GF(256) (127½ being half of 256−1).

Thus, for a five-error correcting code with symmetric generator polynomial over GF(256), the syndromes must be S123, S124, S125, S126, S127, S128, S129, S130, S131, and S132. This list has five syndromes below 127½ and five above, and is thus centered on 127½.

The fact that the syndromes start with a number other than one is irrelevant for the Berlekamp-Massey algorithm, and the first syndrome is treated as if it were S1, the second as if it were S2, etc.

However, this “syndrome offset” does affect Forney's algorithm, the algorithm which evaluates the actual value of the error pattern for a particular byte which is in error.

Conceptually, Forney's algorithm follows after the Chien search, which identifies the byte location of errors. In practice, it is often convenient to run Forney's algorithm in near parallelism with the Chien search.

The standard textbooks provide a formula for Forney's algorithm in the case where there is a syndrome offset. However, unfortunately, this formula involves an extra multiplicative term, which may be termed the “Forney offset-adjustment factor.” It is desirable to avoid the need to calculate this extra factor, which has a separate form for each of the different Reed-Solomon codes.

The present invention provides for an architecture that carries out Forney's algorithm and eliminates the offset-adjustment factor and which has the same structure for all of the different Reed-Solomon codes.

It is important to recognize that all this is irrelevant for the BCH codes. In the Reed-Solomon codes, each symbol is a full byte, so that there are 256 different possible error patterns that can occur in a symbol that is in error. However, for BCH codes, each bit is itself a code symbol; therefore, once one knows which bit is in error, one knows immediately that the error in this bit is a 1 (an error of ‘0’ is, of course, no error at all). Therefore it is not necessary to carry out Forney's algorithm for BCH codes. As is customary, an error of ‘1’ means 1 is XORed with the received bit to get the corrected symbol. In general, the error value is bitwise XORed with the corrupted symbol to generate the corrected symbol.

Therefore, Forney's algorithm is carried out for the Reed-Solomon codes, and it is therefore only for the Reed-Solomon codes that the present architecture is of concern due to the “Forney offset-adjustment factor”.

The present algorithm is different from the textbook implementation, in that the present algorithm uses positive powers where the textbooks have negative powers and the present polynomials are in reverse order. The approach of the present invention differs in these respects from the algorithms disclosed in textbooks. Therefore, it the textbooks are not readily used as a basis for understanding the present Chien and Forney modules.

This has nothing to do with the subfield representation, and the Chien and Forney feedback matrices are in the subfield representation. The present algorithm works in either subfield or standard representations. While none of this affects the BCH Chien search, it is possible to use the Chien search module designed for the Reed-Solomon codes for the BCH codes as well.

Finally, the Forney XOR feedback trees, F1 through F16, are identical to the BCH syndrome trees SB1 through SB16. There are six other BCH syndrome registers and trees, SB17 through SB22, which have no corresponding Forney registers. This makes it possible to reuse the SB registers for the Forney algorithm at significant savings in gate count.

Implementation details of the Reed-Solomon Forney's algorithm and BCH and Reed-Solomon Chien search circuit are discussed below. In all cases, ‘+’ refers to bitwise XOR, not to inclusive OR.

Let Ω (“omega”) refer to the error evaluator polynomial. Let D be the odd part of the error-locator polynomial lambda: i.e., D has the same coefficients as lambda for x to the 1, x to the 3, etc., but the coefficients of x to the 0, x to the 2, etc. are zero in D by definition. Lambda (Λ) is referred to the error-locator polynomial.

These definitions are made to simplify notation and avoid the need to type the Greek symbols for omega and lambda.

The coefficients of Ω and Λ are the output of the Berlekamp-Massey algorithm. D is simply part of Λ.

Let i be the location of an error. Let b be the antilog of i (i.e., alpha to the i power in terms of the usual textbook notation).

Then in the mathematical appendix we show that the following formulae are equivalent to the usual textbook formulae.

For the present implementation of the Chien search, calculate:

g=Λ₀b¹²⁸+Λ₁b¹²⁸+Λ₂b¹²⁶+ . . . Λ₁₆b¹¹².

Check to see if g is zero, and when it is, i, which is the Chien search counter value, is an error location (b is actually alpha to the i power). The only thing g is used for is to run a test to see if g is zero.

In the present version of Forney's algorithm, the error value (i.e., the error pattern within the byte just found to be in error through the zero-test of g) is:

$$e = \frac{{Ω}_{0} {b}^{t} + {Ω}_{1} {b}^{( t - 1 )} + {Ω}_{2} {b}^{( t - 2 )} + … + {Ω}_{t - 1} {b}^{b}}{{Λ}_{0} {b}^{128} + {Λ}_{1} {b}^{127} + {Λ}_{2} 126 + … + {Λ}_{16} {b}^{112}}$$

where t is the number of errors which the Reed-Solomon code is designed to correct (i.e., 2t is the number of redundancy symbols per code block).

Remembering that

D₀=0

D₁=Λ₁

D₂=0

D₃=Λ₃

[symbol]

Calculating the denominator for e for Forney's algorithm is just a matter of taking the odd terms that are needed in order to get g for the Chien search.

The even terms of Λ are added (“add” means bitwise XOR) in parallel with the summing of the odd terms and then send the sum of the odd terms to Forney's algorithm and add the odd and even parts to get g. There's no advantage in re-adding the odd parts for the g calculation since this has already been done for Forney's algorithm.

The only remaining issue is how to get the individual terms that add together to give the results that are needed, i.e., how to get

Λ₀b^{t}, Λ₁^{(t-1)}, Λ₂b^{(t-2)}, etc.

The present invention uses a set of feedback XOR trees which are the heart of these single-term calculating modules. Each XOR tree is used in an 8-bit wide single stage feedback shift-register 23 (such as those shown in FIGS. 3-7).

The XOR tree is labeled by the power of b which it produces: i.e., CR112, if preloaded with Λ₁₆, produces the term

Λ₁₆b¹¹²;

F1, if preloaded with Ωₜ₋₁, will produce the term

Ωₜ₋₁b¹;

and so on.

The term b is actually a function of i, that is, alpha to the i, so that every time that the shift register is clocked, i increments by 1 and the correct power of the new b times the initial value is presented. When the shift registers are first loaded with the Ω and Λ values, their contents correspond to i=0; after one chunk through the XOR trees, their contents correspond to i=1; and so on. No external input is added to the shift registers after the initial Λ and Ω values are fed in from the output of the Berlekamp-Massey module 15.

Furthermore, Galois-field division is required to determine e, which may be generated using the teachings of U.S. patent application Ser. No. ______ entitled “Modular Galois-Field Subfield-Power Integrated Inverter-Multiplier Circuit for Galois-Field Division Over GF(245)”.

With regard to the equation for the error value e, a given D coefficient (say D₀) goes into the same Chien register (CRi register—i.e., CR128 for D₀) for all of the different Reed-Solomon codes. This is not true for the Forney registers (Fi registers). This can be seen by noting that Ω₀ goes into the F register with index t, i.e., Ft. For a specific Reed-Solomon code, t is fixed; however, t is different for the different codes. Thus Ω₀ goes into different registers for the different codes: Ω₀ must end up in register F5 when t=5; Ω₀ must end up in F8 when t=8; and so on.

One very general way to handle this is as follows (alternative implementations are possible; anything that produces the same result is OK). A plurality of serially coupled single stage shift registers, each with its own XOR tree (not shown) which feeds back into itself, may be used. The connections between the single stage shift registers are only for feeding in the Ω coefficients.

The contents of all registers must be preset to zero. Then, the Ω coefficients are fed in from the left, Ω₀ first, followed by Ω₁ and so on, ending with the t−1 term of Ω. This will put the t−1 coefficient of Ω where it belongs in the F1 register. Thus t different Ωs are clocked in and, t is different for the different Reed-Solomon codes (t=5, 8, 10, 12, 13, or 16). With this arrangement, the only dependence on t comes from the number of terms that are clocked in.

A similar design works for the CR registers, although the number of terms clocked in would not depend on t in this case, because the same Λ coefficient always goes into the same CR register (Λ₀ into CR 128, Λ₁ into CR127, etc.).

Because of this lack of t dependence for the Λ coefficients, this sequential approach is not necessary for the Λ coefficients and their CR registers: the coefficients could be loaded in broadside in parallel, for example.

All of this discussion is solely for the Reed-Solomon codes; Forney's algorithm is not performed for BCH codes.

The exponent in the equations is the index i to the CRi or Fi feedback trees and registers; i.e.,

Λ₀b¹²⁸

is generated by register CR128, not register CR0. (CR registers run from CR112 to CR 143, and there is no CR0 register.) The subscript on Λ merely tells us that Λ₀ is the Λ component that must be preloaded into register CR128. A coefficients go into CR registers; Ω coefficients go into F registers.

The i index is also the logical label for the feedback trees: e.g., the syndrome XOR tree SR128 and the Chien search XOR tree CR128 are exactly the same since they have the same index, 128. This fact is of interest in considering whether some circuits can be reused for other functions (e.g., reusing the syndrome registers for the Chien search, which is a design option).

This fact can also be used to simplify some aspects of the design process: no need to enter the same XOR tree twice into the design software—CR128 can be treated as another instance of SR128, if convenient.

The fact that the SB BCH syndrome registers have different XOR feedback trees than the SR Reed-Solomon syndrome registers is indicated by the fact that their indices are different: the SBs range from SB1 to SB22 while the SRs range from SR112 to SR143.

Of particular interest is the fact that the Forney XOR feedback trees, F1 through F16, are identical to the BCH syndrome trees SB1 through SB16. There are six other BCH syndrome registers and trees, SB17 through SB22, which have no corresponding Forney registers. This makes it possible to reuse the SB registers for the Forney algorithm at significant savings in gate count.

Finally, the Reed-Solomon Chien search algorithm outlined above works for the BCH Chien search. Of course, since there is no Forney's algorithm for BCH codes, there is no need to do the Chien search in this unusual way. However, since all the circuitry for the Reed-Solomon codes is available, there is no need to build a separate BCH Chien search module. Therefore the Chien search module is used for BCH codes and Reed-Solomon codes. The A coefficients are loaded in exactly the same way, the feedback XOR trees are the same, and so forth. There are no differences except that Forney's algorithm is not carried out for BCH codes and, for BCH codes, the error value e is always set to 1 for any symbol (i.e., a bit in a BCH code) which is found to be in error by the Chien search.

Thus, a generalized Forney algorithm circuit that is preferably implemented in the form of an integrated circuit has been disclosed. It is to be understood that the described embodiment is merely illustrative of some of the many specific embodiments that represent applications of the principles of the present invention. Clearly, numerous and other arrangements can be readily devised by those skilled in the art without departing from the scope of the invention.

What is claimed is:

1. In a Reed-Solomon BCH error correction decoder that processes encoded input data to generate decoded output data and that comprises syndrome computation circuitry for computing syndromes derived from the input data, Berlekamp-Massey computational circuitry that converts the syndromes into error-locator (lambda) and error-evaluator (omega) polynomials comprising error-location (lambda) and error-value (omega) coefficients, and Chien-Forney circuitry that processes the error-location (lambda) and error-value (omega) coefficients to compute and output error locations and error values, wherein the improvement comprises generalized Forney algorithm circuitry comprising:
syndrome computation circuitry that processes the encoded input data to generate syndromes that are processed by the Berlekamp-Massey computational circuitry to generate the lambda and omega coefficients; and
Chien-Forney circuitry that generates error locations and error values and that comprises:
Chien search circuitry comprising a Chien search algorithm that processes the lambda coefficients to generate error locations;
formal derivative circuitry that computes a derivative of lambda comprising a sum of the odd terms of the error-locator (lambda) polynomials;
omega search circuitry that evaluates the omega coefficients to produce an omega value; and
Forney circuitry comprising Forney's algorithm that processes the derivative of lambda and the omega value to generate error values.

2. The circuit of claim 1 wherein the syndrome computation is performed using a set of one-stage feedback shift registers.

3. The circuit of claim 1 wherein, when the Chien search indicates that a root of lambda has been found, the error value is determined by dividing the error evaluator (omega) polynomial by the value of the odd part of lambda, both evaluated at the root.

4. The circuit of claim 3 wherein the syndrome computation circuitry comprises parity check circuitry that performs parity checks on the input data and outputs syndromes.

5. The decoder of claim 1 wherein the Forney algorithm circuitry comprises Galois field divider circuitry for dividing the output of the omega search circuitry by the output of the formal derivative circuitry to produce the error value.
